(19) United States
(12) Patent Application Publication
(10) Pub. No.: US 2009/0002935 A1
(43) Pub. Date: Jan. 1, 2009

(54) STORAGE DEVICE FIXING STRUCTURE OF MICROCOMPUTER

(76) Inventor: TA-YANG CHENG, Taipei (TW)

Correspondence Address: PATENTTM.US, P. O. BOX 82788, PORTLAND, OR, 97282-0788, US

(21) Appl. No.: 11/770,695

(22) Filed: Jun. 28, 2007

(51) Int. Cl. H05K 7/00

(52) U.S. Cl. 361/685

(57) ABSTRACT

An improved storage device fixing structure of a microcomputer includes a casing; a motherboard installed in the casing, a central processing unit, a plurality of electronic components, a plurality of press key portions, a connector disposed on a side of the motherboard, and a plurality of through holes disposed at appropriate positions of the motherboard; a fixing unit installed on the motherboard and connected to each through hole; and a storage unit fixed onto the fixing unit, such that the storage unit can be installed on the motherboard by the fixing unit to achieve the easy-to-install, easy-to-remove and secured connection effects.

### FIELD OF THE INVENTION

The present invention relates to an improved storage device fixing structure of a microcomputer, and more particularly to a structure capable of installing a storage unit on a motherboard by a fixing unit to achieve the easy-to-install, easy-to-remove and secured connection effects.

### BACKGROUND OF THE INVENTION

In general, a personal computer usually includes a large dissipating component, a power supply, a floppy disk drive and a motherboard, and thus the computer system comes with a very large size. Particularly, if the components and their cables are installed or arranged improperly, then more spaces are wasted. For example, when a motherboard is connected to a power supply, an optical disk drive, a hard disk drive, a burner, a floppy disk drive and other storage devices through different flat cables, and the storage devices are mounted in a multi-layer frame, and the space wasted for their inappropriate arrangement is even larger than the total volume of the motherboard, optical disk drive, and disk drives, and it is the main reason that explains the large size of a computer system.

In view of the large size of a computer, microcomputers are developed and introduced. Although the microcomputers can improve the foregoing shortcomings of personal computers, yet a general microcomputer usually uses an adapting board to connect the storage devices one on top of the other. Such arrangement can achieve a smaller height, but there is an instability issue of the assembly, and thus the storage devices cannot be securely stacked on the motherboard and the performance of the application is affected adversely. What is more, such design cannot meet the requirements of practical applications.

In view of the foregoing shortcomings of the prior art, the inventor of the present invention based on years of experience to conduct extensive researches and experiments, and finally developed an improved storage device fixing structure of a microcomputer in accordance with the present invention.

### SUMMARY OF THE INVENTION

It is a primary objective of the present invention to design an improved storage device fixing structure of a microcomputer to overcome the shortcomings of the prior art.

To achieve the foregoing objective, the present invention provides a structure capable of installing a storage unit on a motherboard by a fixing unit to achieve the easy-to-install, easy-to-remove and secured connection effects.

To achieve the foregoing objective, the present invention further provides an improved storage device fixing structure of a microcomputer, comprising: a casing; a motherboard installed in the casing, at least one central processing unit installed a plurality of electronic components, a plurality of press key portions and connectors disposed on a side of the motherboard, and a plurality of through holes are disposed at appropriate positions of the motherboard; a fixing unit disposed on the motherboard and fixed with each through hole; and a storage unit fixed onto the fixing unit.

The above and other objects, features and advantages of the present invention will become apparent from the following detailed description taken with the accompanying drawing.

### BRIEF DESCRIPTION OF THE DRAWINGS

FIG. 1 is an exploded view of a first preferred embodiment of the present invention;

FIG. 2 is a schematic view of assembling a first preferred embodiment of the present invention;

FIG. 3 is a perspective view of a first preferred embodiment of the present invention;

FIG. 4 is a section view of a first preferred embodiment of the present invention;

FIG. 5 is an exploded view of a second preferred embodiment of the present invention;

FIG. 6 is an exploded view of a third preferred embodiment of the present invention.

### DETAILED DESCRIPTION OF THE PREFERRED EMBODIMENTS

To make it easier for our examiner to understand the objective, innovative features and performance of the present invention, we use preferred embodiments and the accompanying drawings for a detailed description of the present invention.

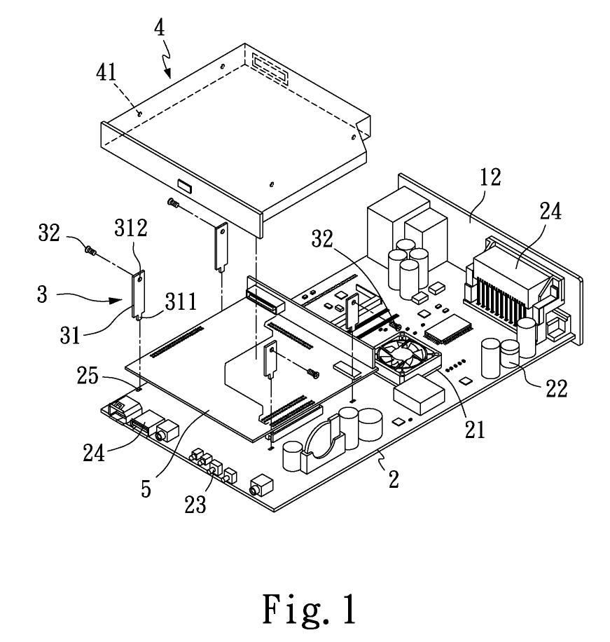

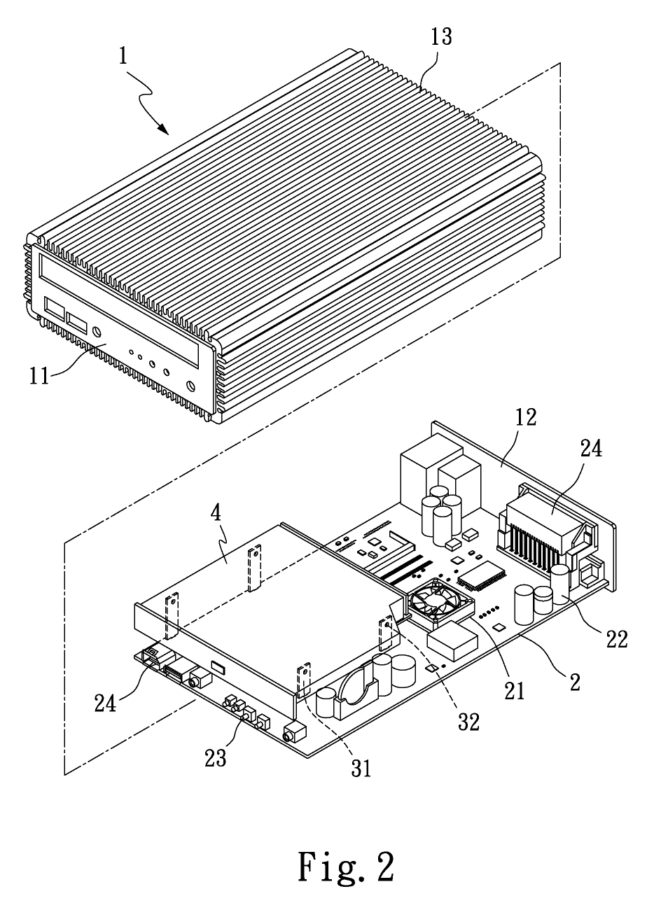

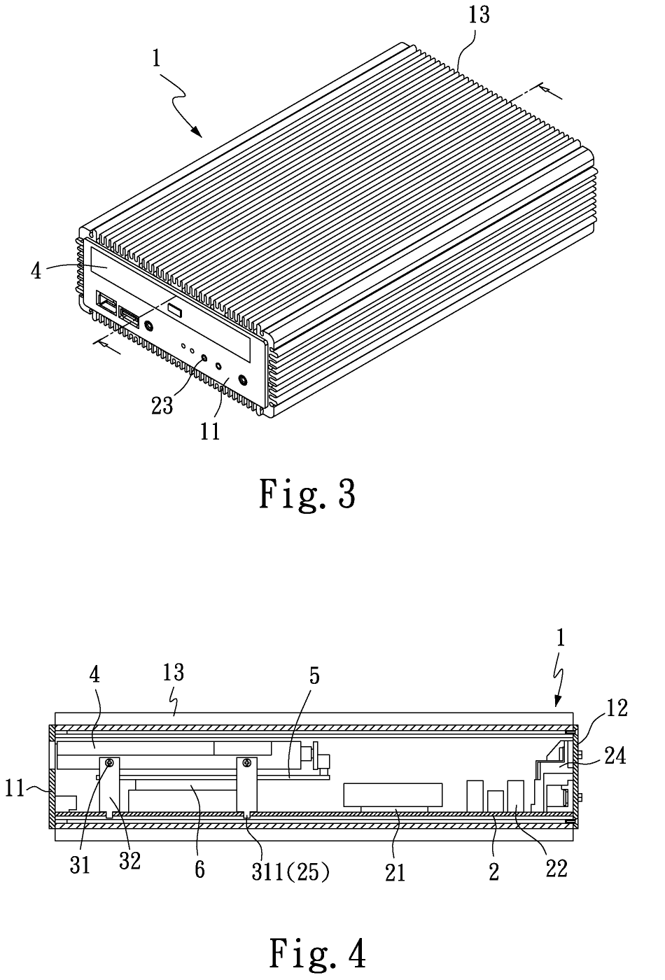

Referring to FIGS. 1 to 4 for an exploded view, a schematic view, a perspective view and a section view of a fixing structure in accordance with a first preferred embodiment of the present invention, the present invention provides an improved storage device fixing structure of a microcomputer, comprising: a casing 1, a motherboard 2, a fixing unit 3 and a storage unit 4, and a front panel 11 and a rear panel 12 are disposed on both ends of the casing 1 respectively, and a plurality of heat dissipating fins 13 are disposed on a surface of the casing 1.

The motherboard 2 is installed in the casing 1, and includes at least one central processing unit 21, a plurality of electronic components 22, a plurality of press key portions 23 and connector 24 exposed from the front and rear panels 11, 12 and disposed on one side of the motherboard 2, and a plurality of through holes 25 are disposed at appropriate positions of the motherboard 2.

The fixing unit 3 is disposed on the motherboard 2 and fixed to each through hole 25, and the fixing unit 3 includes a plurality of corresponding connecting boards 31, and an end of the connecting board 31 has a combining portion 311 for fixing each through hole 25, and another end of the connecting board 31 has a fixing hole 312.

The storage unit 4 is fixed by a connecting a fixing element 32 into a fixing hole 312 of each connecting board 31 of the fixing unit 3, and the storage unit 4 can be a hard disk drive or an optical disk drive. The foregoing structure constitutes a novel and improved storage device fixing structure of a microcomputer.

When the present invention is applied, the fixing unit 3 with a combining portion 311 at an end of each connecting board 31 is inserted into each through hole 25, and the combining portion 311 is soldered, such that each connecting board 31 is fixed perpendicularly to the motherboard 2. After each connecting board 31 of the fixing unit 3 is installed, the storage unit 4 is installed between the connecting boards 31, such that the connecting hole 41 on the storage unit 4 corresponds to the fixing hole 312 on each connecting board 31, and the storage unit 4 is fixed by connecting the fixing element 32 corresponding to the fixing hole 312 with the connecting hole 41. When it is necessary to remove the storage unit 4, the fixing element 32 is removed first for the removal of the storage unit 4, and thus the storage unit 4 can be installed on the motherboard 2 by the fixing unit 3 to achieve the easy-to-install, easy-to-remove and secured connection effects.

When the present invention is applied, a storage unit 6 is installed on the motherboard 2 first, and then an adapting board 5 is connected to the storage unit 6, and another storage unit 4 is connected onto the adapting board 5, so that the connecting hole 41 of the storage unit 4 corresponds to the fixing hole 312 of each connecting board 31, and the fixing element 32 corresponding to the fixing hole 312 is fixed to the connecting hole 41 for installing the storage units one on top of the other, in order to meet the application requirements.

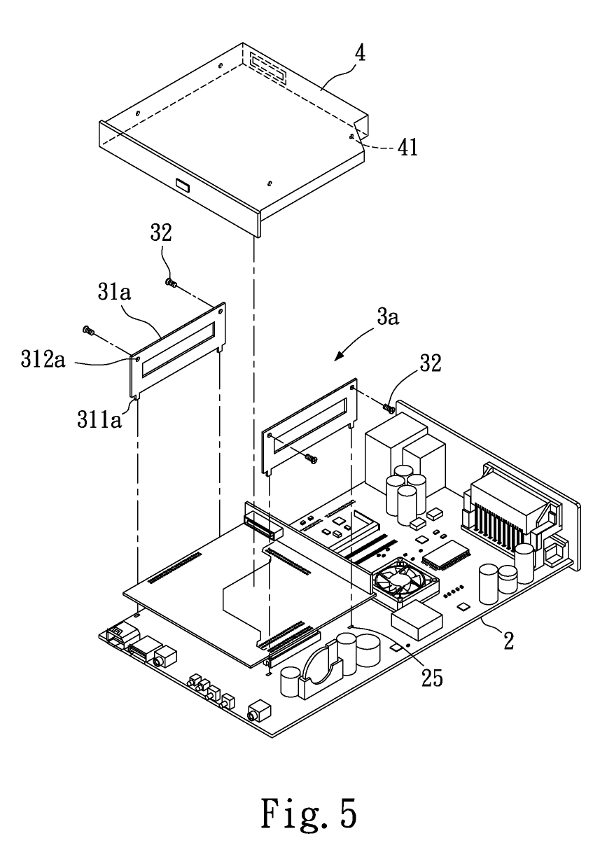

Referring to FIG. 5 for an exploded view of a second preferred embodiment of the present invention, the fixing unit 3 is substantially the same as the first preferred embodiment, and the fixing unit 3a comprises two corresponding connecting boards 31a, and both sides of an end of each connecting board 31a respectively have a combining portion 311a for connecting each through hole 25, and both sides of another end of the each connecting board 31a respectively have a fixing hole 312a corresponding to the fixing element 32 and fixed to the storage unit 4. When the invention is applied, the combining portion 311a of the connecting board 31a corresponding to each through hole 25 is soldered and fixed perpendicularly onto the motherboard 2, and then the storage unit 4 is installed between the connecting boards 31a, so that the connecting hole 41 on the storage unit 4 corresponds to the fixing hole 312a of each connecting board 31a, and the fixing element 32 corresponding to the fixing hole 312a is fixed into the connecting hole 41. When it is necessary to remove the storage unit 4, the fixing element 32 is removed first for the removal of the storage unit 4, so that the storage unit 4 can be installed onto the motherboard 2 by the fixing unit 3a to achieve the easy-to-install, easy-to-remove and secured connection effects.

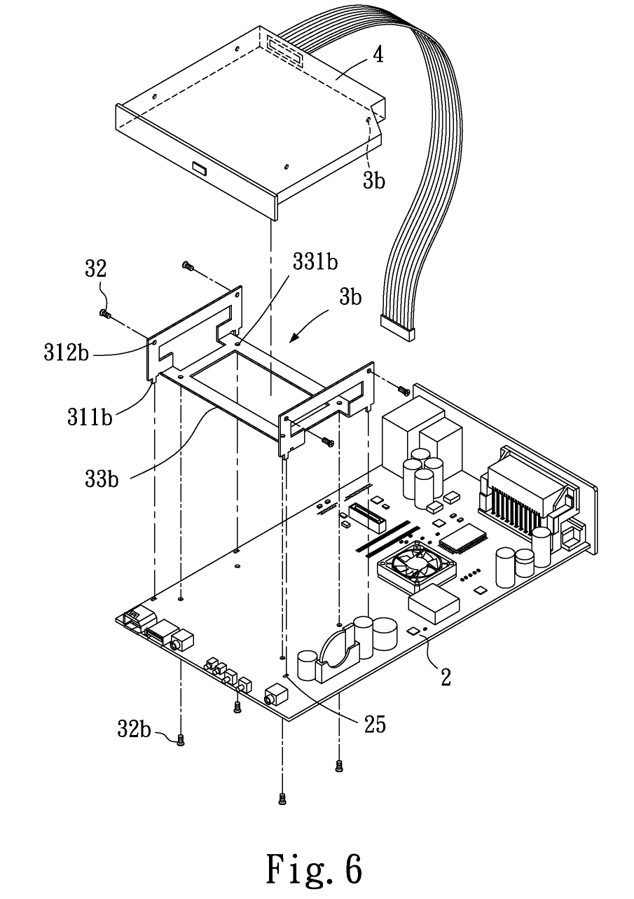

Referring to FIG. 6 for an exploded view of a third preferred embodiment of the present invention, the fixing unit 3 of this preferred embodiment is substantially the same as the first and second preferred embodiments, the fixing unit 3b includes two corresponding connecting boards 31b, and a transverse board 33 connected between the connecting boards 31b, and both sides of an end of each connecting board 31b respectively have a combining portion 311b fixed to each through hole 25, and both sides of another end of each connecting board 31b respectively have a fixing element 32 and a fixing hole 312b fixed to the storage unit 4, and the transverse board 33b has a penetrating hole 331b corresponding to the fixing element 332b and fixed to the motherboard 2.

When the present invention is applied, the combining portion 311b of the connecting board 31b corresponding to each through hole 25 is soldered and fixed perpendicularly onto the motherboard 2, and the fixing element 332b is fixed to the motherboard 2 and a penetrating hole 331b at the bottom of the fixing unit 3b, and the storage unit 4 is installed on the transverse board 33b of the fixing unit 3b, such that both sides of the storage unit 4 correspond to each connecting board 31b, and the connecting hole 41 on the storage unit 4 corresponds to the fixing hole 312b of each connecting board 31b, and the fixing element 32 corresponding to the fixing hole 312b is fixed to the connecting hole 41. When it is necessary to remove the storage unit 4, the fixing element 32 is removed first for the removal of the storage unit 4, such that the storage unit 4 can be installed on the motherboard 2 by the fixing unit 3b to achieve the easy-to-install, easy-to-remove and secured connection effects.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An improved storage device fixing structure of a microcomputer,
comprising:
a casing;
a motherboard, installed in the casing, and having at least one central processing unit, a plurality of electronic components, a plurality of press key portions and connectors, disposed on a side of the motherboard, and a plurality of through holes disposed at appropriate positions of the motherboard;
a fixing unit, installed on the motherboard and fixed to each through hole;
and
a storage unit, fixed onto the fixing unit.

2. The improved storage device fixing structure of a microcomputer as recited in claim 1, wherein the storage unit is a hard disk drive.

3. The improved storage device fixing structure of a microcomputer as recited in claim 1, wherein the storage unit is an optical disk drive.

4. The improved storage device fixing structure of a microcomputer as recited in claim 1, wherein the fixing unit includes a plurality of corresponding connecting boards, and an end of the connecting board has a combining portion for connecting each through hole, and another end of the connecting board has a fixing hole corresponding to the fixing element for fixing the storage unit.

5. The improved storage device fixing structure of a microcomputer as recited in claim 1, wherein the fixing unit includes two corresponding connecting boards, and both sides of an end of each connecting board have a combining portion respectively for fixing each through hole, and both sides of another end of each connecting board have a fixing element and a fixing hole respectively for fixing the storage unit.

6. The improved storage device fixing structure of a microcomputer as recited in claim 1, wherein the fixing unit includes two corresponding connecting boards, and each connecting board is connected to a transverse board, and both sides of an end of each connecting board have a combining portion respectively for fixing each through hole, and both sides of another end of each connecting board have a fixing element and a fixing hole respectively for fixing the storage unit, and a penetrating hole disposed on the transverse board and corresponding to the fixing element for fixing the motherboard and the fixing unit.

7. The improved storage device fixing structure of a microcomputer as recited in claim 1, wherein the casing includes a front panel and a rear panel disposed on both ends of the casing respectively.
